(19) United States
(12) Patent Application Publication
(10) Pub. No.: US 2025/0073821 A1
(43) Pub. Date: Mar. 6, 2025

(54) PROCESSING METHOD OF WAFER

(71) Applicant: DISCO CORPORATION, Tokyo (JP)

(72) Inventors: Akira MIZUTANI, Tokyo (JP); Yusuke OHTAKE, Tokyo (JP); Kei TANAKA, Tokyo (JP)

(21) Appl. No.: 18/802,037

(22) Filed: Aug. 13, 2024

(30) Foreign Application Priority Data
Aug. 31, 2023 (JP) 2023-141245

(51) Int. Cl. B23K 26/53; B23K 101/40; H01L 21/02

(52) U.S. Cl. CPC B23K 26/53; H01L 21/02013; H01L 21/02016; H01L 21/02021; B23K 2101/40

(57) ABSTRACT

A processing method of a wafer includes irradiating the wafer with a laser beam in an annular pattern a predetermined distance from an outer peripheral edge of the wafer, thereby forming an annular modified layer and cracks spreading from the modified layer, before forming the modified layer, storing anticipated regions indicating regions which are part of an annular region that extends along the outer peripheral edge and is to be irradiated with the laser beam and in each of which a failure of formation of the cracks spreading from the modified layer is anticipated, and after the modified layer is formed, grinding the wafer on a side of a back surface thereof to thin the wafer to a finish thickness. In forming the modified layer, the anticipated regions are irradiated with the laser beam under irradiation conditions different from those for the annular region excluding the anticipated regions.

### BACKGROUND OF THE INVENTION

### Field of the Invention

The present invention relates to a processing method of a wafer.

### Description of the Related Art

Keeping in step with the move toward low-profile and high-integration device chips in recent years, development of three-dimensionally stacked semiconductor wafers is under progress. For example, a through-silicon via (TSV) wafer enables connection of electrodes of two chips by bonding both the chips each other with through-silicon vias.

Such a wafer is thinned by being ground in the state of being bonded to a support wafer, which is made from silicon, glass, ceramics, or the like, as a substrate. In general, a wafer is chamfered at an outer peripheral edge thereof. When the wafer is ground extremely thin, the outer peripheral edge is therefore formed into what is generally called a knife edge, so that edge chipping is prone to occur during grinding. There is hence a possibility that the chipping may extend to devices and lead to damage to the devices.

As a countermeasure for a knife edge, an edge trimming technique has been contrived (see JP 2020-057709A). According to this edge trimming technique, a wafer having a device region with devices formed therein, which will hereinafter be referred to as a “device wafer,” is bonded to a support wafer, and the device wafer is then irradiated with a laser beam along an outer peripheral edge of the device region to form an annular modified layer inside the device wafer, thereby suppressing edge chipping, which occurs during grinding of the device wafer, from spreading to the devices.

### SUMMARY OF THE INVENTION

With the technique disclosed in JP 2020-057709A, however, there is a possibility that, depending on the points of the irradiation with the laser beam, differences may arise in elongation of cracks due to plane orientations and thickness variations of the wafer and differences in the reflectance at an incident surface of the laser beam.

The present invention therefore has as an object thereof the provision of a wafer processing method which can form an annular modified layer and cracks along an outer peripheral edge of the wafer while suppressing damage to devices.

In accordance with an aspect of the present invention, there is provided a processing method of a wafer that has a plurality of devices formed on a side of a front surface thereof and is chamfered at an outer peripheral edge thereof. The processing method includes a modified layer forming step of irradiating the wafer with a laser beam of a wavelength having transmissivity for the wafer in an annular pattern along a position on an inner side by a predetermined distance from the outer peripheral edge of the wafer, thereby forming an annular modified layer and cracks spreading from the modified layer, inside the wafer, a storing step of, before the modified layer forming step is performed, storing beforehand anticipated regions indicating regions which are part of an annular region that extends along the outer peripheral edge and is to be irradiated with the laser beam and in each of which a failure of formation of the cracks spreading from the modified layer is anticipated, and a thinning step of, after the modified layer forming step is performed, grinding the wafer on a side of a back surface thereof to thin the wafer to a finish thickness. In the modified layer forming step, the anticipated regions are irradiated with the laser beam under irradiation conditions different from those for the annular region excluding the anticipated regions.

Preferably, in the storing step, the anticipated regions may be preset based on crystal orientations of the wafer.

Preferably, the irradiation conditions for the laser beam applied to the anticipated regions may be different in at least one of output power, a phase, a processing depth of a focal point, an inter-focal point distance, or a pulse width of the laser beam from those for the laser beam applied to the annular region excluding the anticipated regions.

The processing method of the present invention can form the annular modified layer and cracks along the outer peripheral edge of the wafer while suppressing damage to the devices.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting an example of a wafer to which a processing method according to an embodiment of the present invention is to be applied;

FIG. 2 is a fragmentary cross-sectional view taken along line II-II indicated in FIG. 1;

FIG. 3 is a flow chart illustrating a flow of the processing method according to the embodiment;

FIG. 4 is a perspective view depicting how a bonded wafer forming step illustrated in FIG. 3 is performed;

FIG. 5 is a plan view of a bonded wafer, which depicts examples of anticipated regions to be stored in a storing step illustrated in FIG. 3;

FIG. 6 is a side view depicting, partly in cross-section, how a modified layer forming step illustrated in FIG. 3 is performed;

FIG. 7 is a fragmentary cross-sectional view depicting on an enlarged scale a portion of a bonded wafer that has undergone the modified layer forming step illustrated in FIG. 3;

FIG. 8 is a fragmentary cross-sectional view depicting on an enlarged scale a portion of a bonded wafer that has undergone a modification of the modified layer forming step illustrated in FIG. 3; and

FIG. 9 is a fragmentary view depicting, partly in cross-section, how a thinning step illustrated in FIG. 3 is performed.

### DETAILED DESCRIPTION OF THE PREFERRED EMBODIMENT

With reference to the attached drawings, a description will hereinafter be made in detail regarding an embodiment of the present invention. However, the present invention shall not be limited by details that will be described in the following embodiment. The elements of configurations that will hereinafter be described include those readily conceivable to persons skilled in the art and substantially the same ones. Further, the configurations that will hereinafter be described can be combined appropriately. Moreover, various omissions, replacements, and modifications of configurations can be made without departing from the spirit of the present invention.

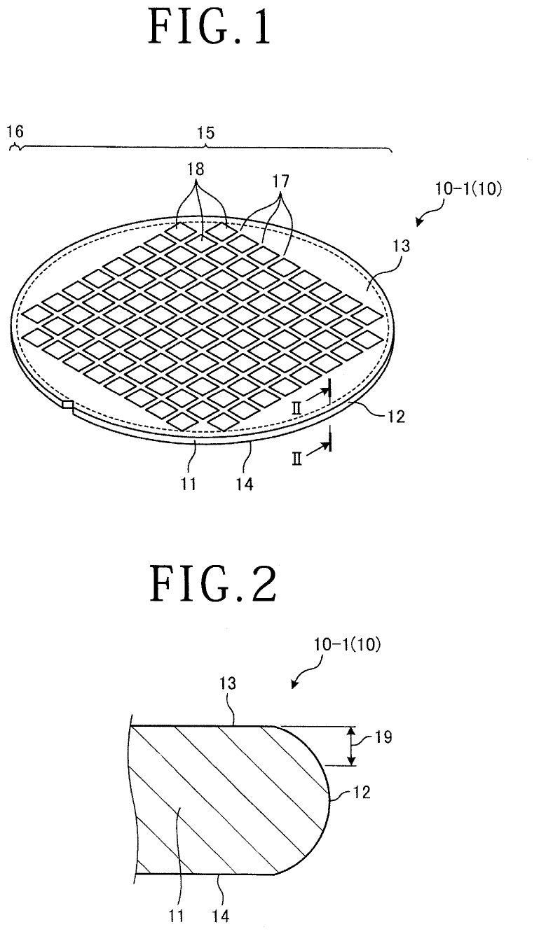

A wafer 10 depicted in FIGS. 1 and 2 is a wafer such as a disk-shaped semiconductor wafer or an optical device wafer that uses silicon (Si), sapphire (Al₂O₃), gallium arsenide (GaAs), silicon carbide (SiC), or the like as a substrate 11, and is a silicon wafer in this embodiment. As depicted in FIG. 2, the wafer 10 has been chamfered at an outer peripheral edge 12 thereof such that the wafer 10 protrudes most toward an outer periphery at a center in a thickness direction thereof and has a round arc profile in cross-section from a front surface 13 to a back surface 14 of the substrate 11.

As depicted in FIG. 1, the wafer 10 has a device layer including, on the side of the front surface 13 of the substrate 11, a central region 15 and an outer peripheral region 16 surrounding the central region 15. The central region 15 has a plurality of scribe lines 17 set in a grid pattern on the front surface 13 of the substrate 11 and devices 18 formed in respective regions defined by the scribe lines 17. The outer peripheral region 16 surrounds the central region 15 over the entirety of a periphery thereof, and has no devices 18 formed therein.

In this embodiment, the devices 18 constitute three-dimensional (3D) NAND flash memories, and include electrode pads and through-silicon vias connected to the electrode pads. When the substrate 11 is thinned and the devices 18 are individually divided from the wafer 10, the through-silicon vias extend to the side of the back surface 14 of the substrate 11. The wafer 10 in this embodiment is therefore what is generally called a TSV wafer in which the individually divided devices 18 each have through-silicon vias. It is however to be noted that the wafer 10 in this invention is not limited to such a TSV wafer having through-silicon vias as in this embodiment and may also be a device wafer having no through-silicon vias.

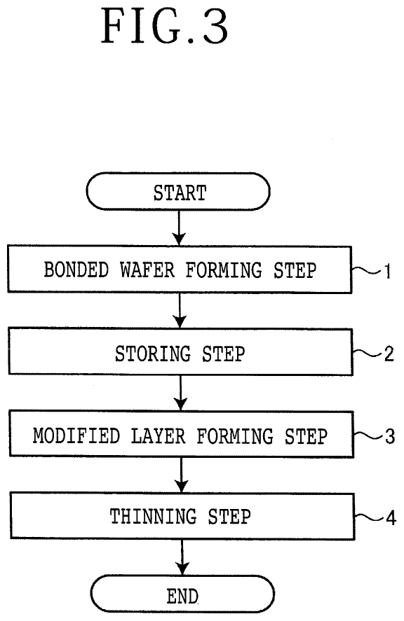

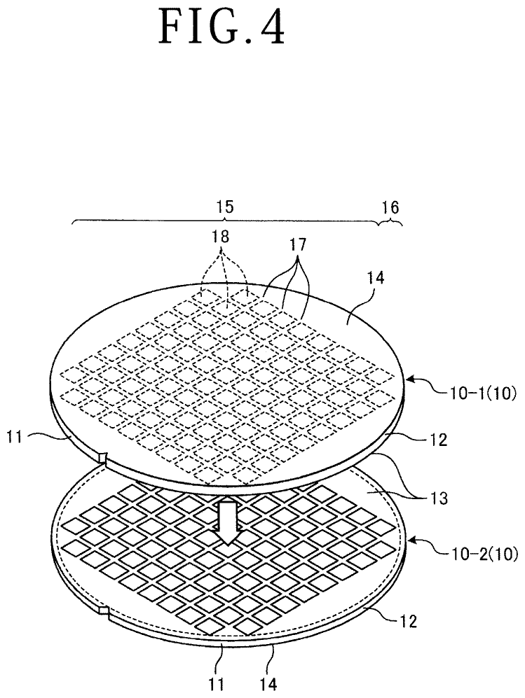

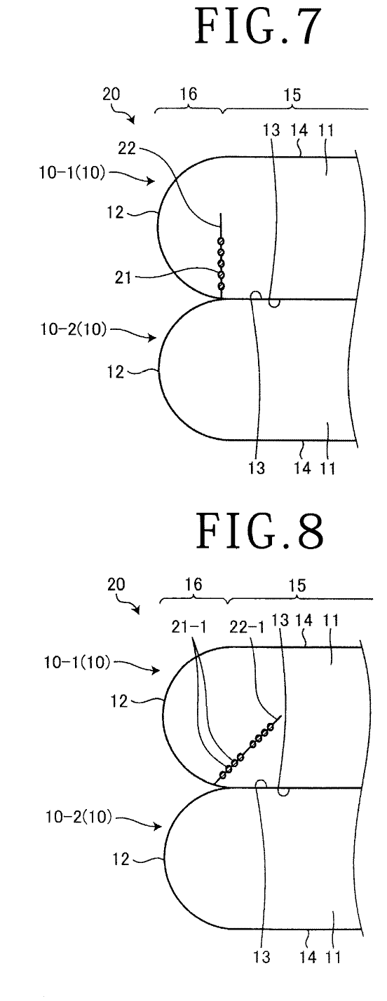

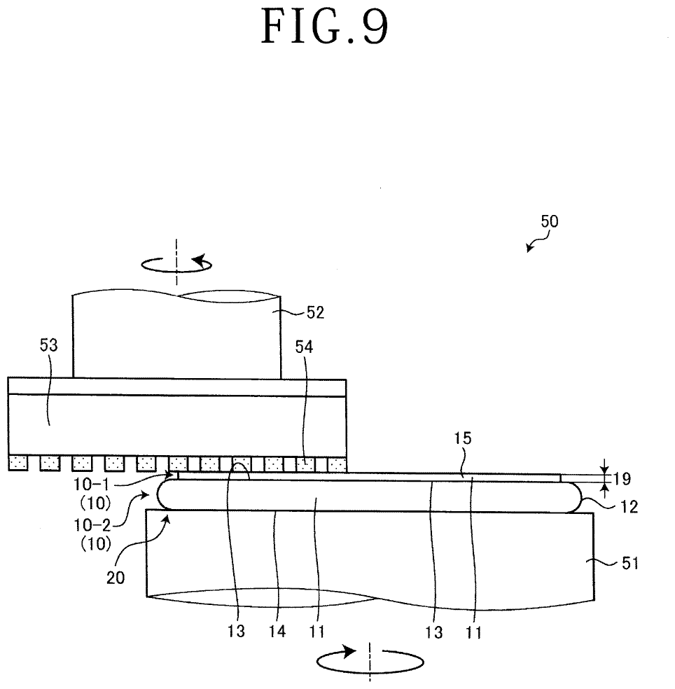

A description will next be made regarding a flow of the processing method according to this embodiment for the wafer 10. FIG. 3 is a flow chart illustrating the flow of the processing method according to this embodiment. As illustrated in FIG. 3, the processing method of this embodiment includes a bonded wafer forming step 1, a storing step 2, a modified layer forming step 3, and a thinning step 4. As will hereinafter be described in detail, in the bonded wafer forming step 1, one of a pair of wafers 10, specifically, a first wafer 10-1, is joined and bonded on the side of the front surface 13 to the other wafer 10, specifically, a second wafer 10-2 (see FIG. 4), in the modified layer forming step 3, trimming start points are formed for removing the outer peripheral region 16 (see FIGS. 6 and 7), and in the thinning step 4, the one wafer 10, specifically, the first wafer 10-1, is then thinned to a predetermined finish thickness 19 (see FIGS. 2 and 9).

It is to be noted that, when the individual wafers 10 are hereinafter distinguished from each other in the paired wafers 10, the one wafer 10 will be referred to as the “first wafer 10-1,” the other wafer 10 will be referred to as the “second wafer 10-2,” and when the individual wafers 10 are hereinafter not distinguished from each other, they will simply be referred to as the “wafer 10.” The other wafer 10, i.e., the second wafer 10-2 that will not be thinned, will be described as a TSV wafer similar to the first wafer 10-1 in this embodiment, but may also be a simple substrate wafer having no pattern in the present invention.

### (Bonded Wafer Forming Step 1)

FIG. 4 is a perspective view depicting how the bonded wafer forming step 1 illustrated in FIG. 3 is performed. The bonded wafer forming step 1 forms a bonded wafer 20 by joining the first wafer 10-1 on the side of the front surface 13 to the second wafer 10-2.

In the bonded wafer forming step 1, the front surface 13 of the first wafer 10-1 and the front surface 13 of the second wafer 10-2 are first brought to face each other with an interval left therebetween as depicted in FIG. 4. The front surface 13 of the first wafer 10-1 and the front surface 13 of the second wafer 10-2 are then bonded together. As a consequence, the bonded wafer 20 is formed.

If a joining layer is disposed between the first wafer 10-1 and the second wafer 10-2 on this occasion, the front surface 13 of the first wafer 10-1 and the front surface 13 of the second wafer 10-2 are bonded together via the joining layer after the joining layer is stacked on one of the front surface 13 of the first wafer 10-1 and the front surface 13 of the second wafer 10-2. It is to be noted that the joining layer may be a double tack tape with self-adhesive material layers stacked on front and back surfaces, respectively, of a base material layer, may be an oxide film, or may be one formed by applying an adhesive that contains resin or the like.

As an alternative, the first wafer 10-1 and the second wafer 10-2 may be directly joined together without using any joining layer. In this case, there may be employed a method that, for example, with at least one of the front surface 13 of the first wafer 10-1 or the front surface 13 of the second wafer 10-2 activated by applying plasma processing to the at least one front surface 13, the first wafer 10-1 and the second wafer 10-2 are bonded and provisionally joined together, and anneal processing is then applied to increase the joint strength. In the plasma processing, with a processing gas such as argon (Ar), nitrogen (N₂), or oxygen (O₂) kept supplied into a chamber housing under a vacuum, radio frequency power is supplied, thereby supplying a plasma state gas to the above-described at least one front surface 13.

Further, examples of a method for applying the anneal processing include a single wafer rapid thermal anneal (RTA) method that rapidly heats a plurality of provisionally joined wafers one after one in the chamber housing, a batch-type anneal processing method that concurrently subjects a plurality of provisionally joined wafers, which are arranged in a quartz furnace tube, to heat treatment by heating them with infrared rays by a heater from outside, and, without limited to the method that heats by infrared rays, a method that heats a plurality of provisionally joined wafers on a hot plate. It is to be noted that the anneal processing may be applied after the storing step 2 or the modified layer forming step 3 insofar as it is performed before the thinning step 4 to be mentioned subsequently herein.

In this embodiment, the first wafer 10-1 and the second wafer 10-2 are bonded together between the sides of the front surfaces 13 thereof. If the second wafer 10-2 is a substrate wafer, however, the first wafer 10-1 may be bonded on the side of the front surface 13 thereof to either side of the second wafer 10-2. Further, in the processing method of this embodiment, each processing of the first wafer 10-1 is performed with the first wafer 10-1 and the second wafer 10-2 bonded together between the sides of the front surfaces 13 thereof. However, the wafer 10 to be processed in the present invention is not necessarily limited to the wafer 10 that makes up the bonded wafer 20, and the single wafer 10 may also be processed. In other words, it is not necessarily required to perform the bonded wafer forming step 1.

### (Storing Step 2)

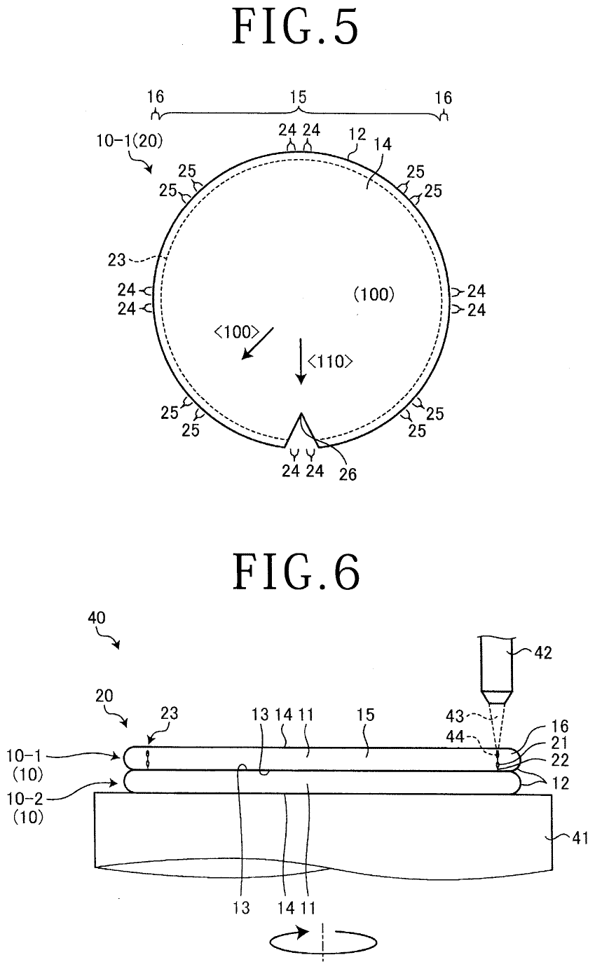

FIG. 5 is a plan view of the bonded wafer 20, which depicts examples of preset anticipated regions 24 and 25 to be stored in the storing step 2 illustrated in FIG. 3. In this embodiment, the storing step 2 is performed after the bonded wafer forming step 1 is performed but before the modified layer forming step 3 is performed. The storing step 2 stores beforehand the preset anticipated regions 24 and 25 which are part of an annular region 23 that extends along the outer peripheral edge 12 and is to be irradiated with a laser beam 43 (see FIG. 6).

In the below-mentioned modified layer forming step 3, the annular region 23 is located at a position on an inner side by a predetermined distance from the outer peripheral edge 12, and, specifically, is a boundary between the central region 15 and the outer peripheral region 16. The anticipated regions 24 and 25 indicate regions in each of which a failure of formation of cracks 22 (see FIG. 6) that spread from a modified layer 21 (see FIG. 6) to be formed in the below-mentioned modified layer forming step 3 is anticipated.

The anticipated regions 24 and 25 are preset, for example, based on crystal orientations of the first wafer 10-1. The wafer 10 tends to break along cleavage planes. In the first wafer 10-1 which is a silicon wafer in this embodiment, for example, cleavage planes are crystal planes {100}, {111}, {110}, and so on. As the wafer 10 is unlikely to be broken along planes slightly inclined from the cleavage planes, the cracks 22 are unlikely to spread in directions inclined by greater than 0 degrees and smaller than 22.5 degrees, especially in directions inclined by 1 degree or greater and smaller than 5 degrees from the directions along the crystal planes.

In the first wafer 10-1 depicted in FIG. 5, for example, the crystal plane orientation of a principal plane parallel to the front surface 13 and the back surface 14 is (100), and the crystal orientation indicated by a notch 26 is <110>. In this case, a region in which an angle θ1 between a tangent to the planar annular region 23 in the principal plane (back surface 14) and a {110} crystal plane is 0 degrees<θ1<22.5 degrees, preferably, 1 degree≤θ1<5 degrees, is preset as the anticipated region 24. On the other hand, a region in which an angle θ2 between a tangent to the planar annular region 23 in the principal plane (back surface 14) and a {100} crystal plane is 0 degrees <θ2<22.5 degrees, preferably, 1 degree≤θ2<5 degrees, is preset as the anticipated region 25. It is to be noted that the anticipated regions 24 and 25 are also preset in a similar manner in a case where a principal plane has a (111) or (110) crystal plane orientation.

If the anticipated regions 24 and 25 are preset based on crystal orientations as described above, the crystal orientations of the wafer 10 are registered beforehand, or use is made of a system that recognizes the crystal orientations of the wafer 10, for example. In the storing step 2, the anticipated regions 24 and 25 are preset based on the crystal orientations registered beforehand or recognized by the system.

### (Modified Layer Forming Step 3)

FIG. 6 is a side view depicting, partly in cross-section, how the modified layer forming step 3 illustrated in FIG. 3 is performed. FIGS. 7 and 8 are fragmentary cross-sectional views depicting on an enlarged scale a portion of the bonded wafer 20 that has undergone the modified layer forming step 3 illustrated in FIG. 3 and a portion of another bonded wafer that has undergone a modification or the modified layer forming step 3, respectively. The modified layer forming step 3 is performed after the storing step 2 is performed. The modified layer forming step 3 forms a plurality of annular modified layers 21 and cracks 22, which spread from the modified layer 21, along the position on the inner side by the predetermined distance from the outer peripheral edge 12 of the first wafer 10-1.

In the modified layer forming step 3, the modified layers 21 and the cracks 22 are formed inside the first wafer 10-1 through stealth dicing by a laser processing machine 40. The laser processing machine 40 includes a holding table 41 and a laser beam irradiation unit 42. The holding table 41 holds the wafers 10 on a holding surface thereof, and is rotatable about a vertical axis of rotation. The laser beam irradiation unit 42 irradiates, with the pulsed laser beam 43, the first wafer 10-1 held on the holding table 41 via the second wafer 10-2. The laser processing machine 40 further includes an undepicted moving unit that moves the holding table 41 and the laser beam irradiation unit 42 relative to each other, an undepicted imaging unit that captures an image of the first wafer 10-1 held on the holding table 41 via the second wafer 10-2, and so on.

In the modified layer forming step 3, the annular modified layers 21 are each formed inside the first wafer 10-1 by applying the pulsed laser beam 43 from the side of the back surface 14 of the first wafer 10-1 and along the position on the inner side by the predetermined distance from the outer peripheral edge 12 of the first wafer 10-1. The expression “the position on the inner side by the predetermined distance from the outer peripheral edge 12” specifically means the annular region 23 as the boundary between the central region 15 and the outer peripheral region 16. The pulsed laser beam 43 is a pulsed laser beam of a wavelength having transmissivity for the first wafer 10-1, and is, for example, infrared rays (IR).

The term “modified layer 21” means a region in which one or more of the density, the refractive index, the mechanical strength, and other physical properties have changed to a level or levels different from the corresponding one or ones of surroundings. The modified layer 21 is, for example, a fusion treated region, a cracked region, a dielectric breakdown region, a refractive index change region, a region where two or three of these regions exist mixed together, or the like. The modified layer 21 is lower in mechanical strength or the like than the other regions in the first wafer 10-1.

In the modified layer forming step 3, the second wafer 10-2 is first held on the side of the back surface 14 thereof by suction on the holding surface (upper surface) of the holding table 41. An alignment is then performed between the first wafer 10-1 and a condenser of the laser beam irradiation unit 42. Described specifically, the holding table 41 is moved by the undepicted moving unit to an irradiation region below the laser beam irradiation unit 42. An image of the first wafer 10-1 is then captured by the undepicted imaging unit, followed by an alignment to allow an irradiating portion of the laser beam irradiation unit 42 to face in a vertical direction toward the position on the inner side by the predetermined distance from the outer peripheral edge 12 in the first wafer 10-1, and then to set a focal point 44 of the pulsed laser beam 43 inside the first wafer 10-1.

In the modified layer forming step 3, the pulsed laser beam 43 from the laser beam irradiation unit 42 is next applied from the side of the back surface 14 of the first wafer 10-1, with the holding table 41 kept rotating about the vertical axis of rotation. The pulsed laser beam 43 is therefore applied in the annular pattern along the position on the inner side by the predetermined distance from the outer peripheral edge 12 in the first wafer 10-1.

Here, the pulsed laser beam 43 is irradiated under different irradiation conditions between the anticipated regions 24 and 25 stored beforehand in the storing step 2 and the annular region 23 excluding the anticipated regions 24 and 25. Between the anticipated regions 24 and 25 and the annular region 23 excluding the anticipated regions 24 and 25, the irradiation conditions for the pulsed laser beam 43 are changed in at least one of the output power, the phase, the processing depth of each focal point 44, the distance between the focal points 44, or the pulse width of the pulsed laser beam 43. Described specifically, the irradiation conditions are set, for example, such that the laser intensity is stronger at processing points, such as greater output power, a shorter distance between the focal points 44, or a smaller pulse width of the pulsed laser beam 43, in the anticipated regions 24 and 25 than in the annular region 23 excluding the anticipated regions 24 and 25. The irradiation conditions may also be set, for example, such that the extension of cracks is promoted, such as formation of a phase pattern by a spatial light modulator (for example, a liquid crystal on silicon-spatial light modulator (LCOS-SLM)) in such a manner as to form an aberration or deepening of the focal point 44, in the anticipated regions 24 and 25 compared with in the annular region 23 excluding the anticipated regions 24 and 25.

As a consequence, in the first wafer 10-1, the annular modified layers 21 are formed along the position on the inner side by the predetermined distance from the outer peripheral edge 12, and the cracks 22 are allowed to spread from the modified layers 21. As depicted in FIG. 7, it is preferred to form, in the modified layer forming step 3, the modified layers 21 by the irradiation of the pulsed laser beam 43 such that the cracks 22 spreading from the modified layers 21 appear on the side of the front surface 13 of the first wafer 10-1. It is to be noted that the cracks 22 may appear not only on the side of the front surface 13 but also on the side of the back surface 14 of the first wafer 10-1.

It is also to be noted that, in the modified layer forming step 3, the first wafer 10-1 is irradiated a plurality of times with the pulsed laser beam 43 with the height position of the focal point 44 of the pulsed laser beam 43 changed every time in the thickness direction of the first wafer 10-1. As an alternative, the pulsed laser beam 43 may have a plurality of focal points 44 apart from one another in the thickness direction of the first wafer 10-1, and the first wafer 10-1 may be irradiated with the pulsed laser beam 43 such that a plurality of modified layers 21 are similarly formed along a direction perpendicular to the front surface 13 of the first wafer 10-1. As another alternative, it is also possible to use a pulsed laser beam split into a plurality of beamlets in the traveling direction of the pulsed laser beam, a pulsed laser beam split into a plurality of beamlets in directions perpendicular to the traveling direction of the pulsed laser beam, or an oval-shaped pulsed laser beam having a major axis in the traveling direction of the pulsed laser beam and a minor axis in a direction orthogonal to the traveling direction of the pulsed laser beam.

If the pulsed laser beam 43 is irradiated a plurality of times from the side of the back surface 14 of the first wafer 10-1, a plurality of modified layers 21 are similarly formed one after another from the side of the front surface 13 toward the side of the back surface 14. Here, the expression “perpendicular to the front surface 13 of the first wafer 10-1” more specifically indicates that an inclination of an approximate plane, which is formed by approximating the entire spreading cracks 22 to a plane, is in ±5 degrees, preferably in ±2 degrees.

In the example illustrated in FIGS. 6 and 7, the modified layers 21 are formed along the direction perpendicular to the front surface 13 of the first wafer 10-1, and the cracks 22 are formed spreading in the direction perpendicular to the front surface 13 of the first wafer 10-1, respectively, in the modified layer forming step 3. As depicted as the modification of the modified layer forming step 3 in FIG. 8, a plurality of modified layers 21-1 and cracks 22-1 may be formed along a side surface of a truncated circular cone, which has an inclination from the side of the front surface 13 toward the side of the back surface 14 of the first wafer 10-1. When the modified layers 21 or 21-1 and the cracks 22 or 22-1 are formed in the annular pattern along the entire periphery of the first wafer 10-1 in the first wafer 10-1, the modified layer forming step 3 is completed.

### (Thinning Step 4)

FIG. 9 is a side view depicting, partly in cross-section, how the thinning step 4 illustrated in FIG. 3 is performed. The thinning step 4 is performed after the modified layer forming step 3 is performed. The thinning step 4 grinds the wafer 10 (in this embodiment, the first wafer 10-1 of the bonded wafer 20) from the side of the back surface 14 to thin the first wafer 10-1 to the predetermined finish thickness 19.

In the thinning step 4 in this embodiment, the first wafer 10-1 is thinned to the predetermined finish thickness 19 by grinding it on the side of the back surface 14 with a grinding machine 50. The grinding machine 50 includes a holding table 51, a spindle 52 as a rotating shaft member, a grinding wheel 53 attached to a lower end of the spindle 52, grinding stones 54 secured to a lower surface of the grinding wheel 53, and an undepicted grinding fluid supply unit. The grinding wheel 53 rotates about an axis of rotation which is parallel to an axis of rotation of the holding table 51.

In the thinning step 4, the second wafer 10-2 is first held on the side of the back surface 14 thereof by suction on a holding surface of the holding table 51. With the holding table 51 kept rotating about its axis of rotation, the grinding wheel 53 is then rotated about its axis of rotation. A grinding fluid is supplied to a processing point by the undepicted grinding fluid supply unit, and at the same time, the grinding stones 54 of the grinding wheel 53 are brought closer at a predetermined feed rate toward the holding table 51, whereby the first wafer 10-1 is ground at the back surface 14 thereof by the grinding stones 54 and is thinned to the predetermined finish thickness 19.

Here, by an external force under which the grinding stones 54 press a ground surface of the first wafer 10-1, the edge material of the outer peripheral region 16 of the first wafer 10-1 is removed using the modified layers 21 as trimming start points and the modified layers 21 and the cracks 22 as an interface.

As has been described above, the processing method according to this embodiment for the wafer 10 recognizes beforehand (presets) the anticipated regions 24 and 25 indicating regions in which the cracks 22 are unlikely to spread and regions in which cracks 22 are unlikely to be interconnected together, when the wafer 10 is irradiated with the pulsed laser beam 43 along the annular region 23 on the inner side by the predetermined distance from the outer peripheral edge 12 of the wafer 10. Here, the pulsed laser beam 43 is applied to the anticipated regions 24 and 25 under irradiation conditions different from those for the annular region 23 excluding the anticipated regions 24 and 25. Described specifically, processing is applied to the anticipated regions 24 and 25 under processing conditions that promote the spreading of the cracks 22 and the interconnection of the cracks 22 themselves.

This makes it possible to further ensure the occurrence of cracks 22 around the entirety of the modified layers 21 formed in the annular pattern and hence have the cracks 22 connected to the adjacent modified layers 21 and cracks 22. Trimming start points are hence formed more clearly between the central region 15 and the outer peripheral region 16, thereby exhibiting an advantage that can suppress processing failures, such as breakage of the wafer 10 and damage to the devices 18, when the outer peripheral region 16 is removed by a grinding load during grinding processing in the following thinning step 4. Moreover, the profile of the wafer 10 that has undergone the removal of the outer peripheral region 16 can be controlled with a smaller deviation from a desired profile, so that the trimming can be applied with the smaller deviation from the desired profile.

It is to be noted that the present invention shall not be limited to the above-described embodiment and modification. In other words, the present invention can be practiced with various modifications within the scope not departing from the spirit of the present invention. Cracks 22 may also be unlikely to propagate, for example, if there are regions varied in thickness or regions low in transmittance in a film, such as an oxide film, formed over the back surface 14 of the wafer 10. Taking these regions as the anticipated regions 24 and 25, irradiation conditions may hence be changed.

In addition, the outer peripheral region 16 may also be removed beforehand by applying an external force before the thinning step 4 is performed. Described specifically, examples may include a method that applies an external force in a shear direction by pressing the outer peripheral region 16 from above, a method that applies an external force in the shear direction by lifting up the outer peripheral region 16, or a method that crushes the outer peripheral region 16 by a roller. Without being limited to a mechanical external force, the external force may also be vibrations by ultrasonic waves or an external force applied in a radial direction by expanding an expandable tape bonded to the back surface 14 of the first wafer 10-1.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing method of a wafer that has a plurality of devices formed on a side of a front surface thereof and is chamfered at an outer peripheral edge thereof, comprising:
a modified layer forming step of irradiating the wafer with a laser beam of a wavelength having transmissivity for the wafer in an annular pattern along a position on an inner side by a predetermined distance from the outer peripheral edge of the wafer, thereby forming an annular modified layer and cracks spreading from the modified layer, inside the wafer;
a storing step of, before the modified layer forming step is performed, storing beforehand anticipated regions indicating regions which are part of an annular region that extends along the outer peripheral edge and is to be irradiated with the laser beam and in each of which a failure of formation of the cracks spreading from the modified layer is anticipated; and
a thinning step of, after the modified layer forming step is performed, grinding the wafer on a side of a back surface thereof to thin the wafer to a finish thickness,
wherein, in the modified layer forming step, the anticipated regions are irradiated with the laser beam under irradiation conditions different from those for the annular region excluding the anticipated regions.

2. The processing method according to claim 1, wherein, in the storing step, the anticipated regions are preset based on crystal orientations of the wafer.

3. The processing method according to claim 1, wherein the irradiation conditions for the laser beam applied to the anticipated regions are different in at least one of output power, a phase, a processing depth of a focal point, an inter-focal point distance, or a pulse width of the laser beam from those for the laser beam applied to the annular region excluding the anticipated regions.
